(19) United States
(12) Patent Application Publication
(10) Pub. No.: US 2024/0368759 A1
(43) Pub. Date: Nov. 7, 2024

(54) METHODS AND SYSTEMS FOR SELECTIVE ATOMIC LAYER DEPOSITION

(71) Applicant: LOTUS APPLIED TECHNOLOGY, LLC, BEAVERTON, OR (US)

(72) Inventor: ERIC DICKEY, BEAVERTON, OR (US)

(73) Assignee: LOTUS APPLIED TECHNOLOGY, LLC, BEAVERTON, OR (US)

(21) Appl. No.: 18/456,802

(22) Filed: Aug. 28, 2023

Related U.S. Application Data
(60) Provisional application No. 63/500,520, filed on May 5, 2023.

(51) Int. Cl. C23C 16/455; C23C 16/48

(52) U.S. Cl. CPC C23C 16/45536; C23C 16/482; C23C 16/483

(57) ABSTRACT

This disclosure relates to methods and systems for selective atomic layer deposition. A substrate may be completely exposed to a precursor gas. Meanwhile, a localized energy scans the substrate. Methods and systems are disclosed herein for either directing the precursor gas away from the selected regions or limiting reactivity of the precursor gas outside of the selected regions. A thin film of reaction product is formed in the selected regions of the substrate and not on undesired surfaces.

### CROSS-REFERENCE TO RELATED APPLICATIONS

This application claims the benefit of U.S. Provisional Patent Application Ser. No. 63/500,520 filed May 5, 2023, titled “METHODS AND SYSTEMS FOR SELECTIVE ATOMIC LAYER DEPOSITION,” the entire contents of which are incorporated herein by reference.

### COPYRIGHT NOTICE

©2023 Lotus Applied Technology, LLC. A portion of the disclosure of this patent document contains material that is subject to copyright protection. The copyright owner has no objection to the facsimile reproduction by anyone of the patent document or the patent disclosure, as it appears in the Patent and Trademark Office patent file or records, but otherwise reserves all copyright rights whatsoever. 37 CFR § 1.71 (d).

### TECHNICAL FIELD

This disclosure relates generally to manufacturing processes and in particular to methods and systems for selective atomic layer deposition.

### BACKGROUND

An overview of conventional ALD processes is provided in Atomic Layer Epitaxy (T. Suntola and M. Simpson, eds., Blackie and Son Ltd., Glasgow, 1990), which is incorporated herein by reference. Numerous patents and publications describe atomic layer deposition (ALD) and sequential chemical vapor deposition (CVD). Atomic Layer Deposition (ALD) and chemical vapor deposition (CVD) can utilize the same precursors. However, in contrast to CVD, ALD involves a sequential exposure of a surface to the precursors. Additional steps, including purge steps, can occur in between precursor exposures, reducing the reaction byproducts trapped in the thin film of product produced by the chemical reactions.

Additionally, ALD provides conformal films, even in high-aspect ratio features. ALD reactions tend to coat any surface sequentially exposed to the precursors, including the walls of the reaction chamber and any other equipment present in the reaction chamber.

A need exists for ALD methods and systems that provide formation of thin films only on selected regions of a surface.

### BRIEF DESCRIPTION OF THE DRAWINGS

The embodiments disclosed herein will become more fully apparent from the following description and appended claims, taken in conjunction with the accompanying drawings. The drawings depict primarily generalized embodiments (and are not necessarily to scale), which embodiments will be described with additional specificity and detail in connection with the drawings in which:

FIG. 1 illustrates a cross-sectional view of one embodiment of an exemplary system for selective atomic layer deposition.

FIG. 2 illustrates a cross-sectional view of another embodiment of an exemplary system for selective atomic layer deposition.

FIG. 3 illustrates a cross-sectional view of another embodiment of an exemplary system for selective atomic layer deposition.

FIG. 4 illustrates a cross-sectional view of another embodiment of an exemplary system for selective atomic layer deposition.

FIG. 5 illustrates an exemplary rotary system with one embodiment of a rotary platen according to the methods and systems disclosed herein.

FIG. 6 illustrates an exemplary roll-to-roll system according to the methods and systems disclosed herein.

FIG. 7 illustrates another exemplary rotary system according to the methods and systems disclosed herein.

### DETAILED DESCRIPTION

Disclosed herein are processes and systems for thin film deposition. Disclosed herein are methods and system for depositing thin films, where the ALD process can optionally be performed in the same chamber where other processes are performed. For example, utilizing the methods and systems disclosed herein, ALD can be performed in the same chamber as high-speed printing processes with a printhead. While not a requirement for using the embodiments disclosed herein, performing ALD in the same chamber as other process, could be advantageous.

Furthermore, the methods and systems disclosed herein can allow for reduced waste of precursor gases to achieve the same film thickness. While not a requirement for using the embodiments disclosed herein, reduced waste of unused precursor gases could be advantageous both economically and environmentally. Other advantages and benefits of the embodiments disclosed herein will become apparent as the embodiments are discussed in detail below.

Additionally, the methods and systems disclosed herein can achieve the qualities of high-temperature thermal ALD, but without overheating the substrate. For example, film density or electrical properties can be improved by elevated-temperature thermal ALD. The methods and systems disclosed herein allow for temporary elevated temperatures at the surface, but without overheating the bulk substrate. Localized energy can be used to repeatedly temporarily heat the surface to achieve thermal ALD without heating the entire substrate. Beneficially, even thermally sensitive substrates can be coated using the methods and systems disclosed herein.

In one embodiment, methods of depositing a thin film include providing a substrate with a selected region to be coated and then repeatedly exposing the selected region to a precursor gas and scanning the selected region with a localized energy. Exposure to the precursor gas results in some of the precursor gas adsorbing on the selected region of the substrate. Scanning the selected region with the localized energy results in at least some of the adsorbed precursor in the selected region converting to a product with a growth-rate less than or equal to about one molecular layer of the product. Each subsequent exposure of the selected region of the substrate to the precursor gas and the localized energy results in at least some of the adsorbed precursor converting to the product in the selected region. A thin film of the product is formed with high resolution in the selected region of the substrate. The product may be an element (such as a metal), a compound (such as an oxide, nitride, etc.), or combinations thereof.

Scanning the selected region with the localized energy preferably heats the selected region and enables conversion of at least some of the adsorbed precursor to the product. Scanning the selected region with the localized energy may also cause photolytic decomposition of at least some of the adsorbed precursor and enables conversion of the adsorbed precursor to the product. In some embodiments, the localized energy source is selected to both heat the substrate and photolytically decompose the adsorbed precursor gas molecules.

The localized energy is preferably a laser beam but may also be visible, ultraviolet, or infrared radiation from a light source, such as a halogen rapid thermal processing lamp.

Preferably, the localized energy is selected for absorption by the substrate and is not substantially absorbed by the precursor gas molecules (such as a laser wavelength that is primarily absorbed by the substrate and/or product film but is not substantially absorbed by the gas phase precursor gas molecules). This results in heating the substrate contacted with the localized energy without substantial gas-phase reaction of the precursor gas. The precursor gas is preferably only reactive at or above an elevated temperature (either by itself or by reaction with one or more reagent gases) but substantially non-reactive below the elevated temperature. This limits conversion of gas-phase precursor gas to the product and limits conversion of the adsorbed precursor outside the selected region heated by the localized energy. This provides high resolution to the product formed on the selected region of the substrate. This also limits precipitation of gas-phase formed product.

Alternatively, the precursor gas may be selected to preferentially only adsorb at or above a particular elevated temperature. In this embodiment, the precursor gas would only absorb in the selected regions heated by the localized energy. High-resolution of the product formed would be achieved when the localized energy is a laser beam.

The methods may further include cooling the selected region in between scanning the selected region with the localized energy. Cooling the selected region may involve allowing enough time (e.g., 0.1 seconds) in between scans with the localized energy to let the selected region passively cool. Active cooling may also be employed, such as actively cooling the backside of the substrate. In some embodiments, the methods may be performed in a cold-wall reactor chamber. The selected region may not need to be cooled to ambient temperatures. It may be sufficient if the selected region is only cooled in between scans to temperatures at which the precursor gas is substantially non-reactive and/or does not readily adsorb.

In certain embodiments, only the regions outside of the selected region are actively cooled, thereby reducing the reaction of the precursor gas outside the selected region.

The methods may further include directing the precursor gas away from the selected region prior to scanning the selected region with the localized energy, thereby limiting conversion of gas-phase precursor gas to the product, and thereby limiting precipitation of gas-phase formed product. Directing the precursor gas away from the selected region may involve evacuating the precursor gas from the selected region of the substrate.

Alternatively or additionally, directing the precursor gas away from the selected region may involve displacing the precursor gas proximal the selected region with a secondary gas. Non-limiting examples of the secondary gas include a background gas, a reagent gas, or mixtures thereof. “Background gas,” as used herein, means under the process conditions present, the gas is substantially non-reactive with the precursor gas. Likewise, “reagent gas,” as used herein, means under process conditions present, the gas is reactive with the adsorbed precursor to form the product after activation of the adsorbed precursor by the localized energy and wherein the reagent gas is substantially non-reactive with the precursor gas absent activation by the localized energy. Activation of the adsorbed precursor and precursor gas by the localized energy can include indirect activation, such as thermal activation by heat radiating (or otherwise transferring) from the substrate and/or existing product molecules, and direct activation by the reagent gas absorbing energy from the localized energy.

Displacing the precursor gas proximal the selected region with the secondary gas may involve introducing the secondary gas adjacent the localized energy and at a sufficient pressure and flow rate to form a gas curtain surrounding a pathway of the localized energy, thereby limiting interaction of gas-phase precursor gas with the localized energy. A physical shroud may be used to direct the flow of the secondary gas around the localized energy, aiding formation of the gas shroud.

Directing the precursor gas away from the selected region and scanning the selected region with the localized energy may occur simultaneously or substantially simultaneously. For example, directing the precursor gas away from the selected region may be initiated prior to scanning the selected region with the local and continue while scanning the selected region with the localized energy.

In other embodiments, instead of directing the precursor gas away from the selected region, exposing the selected region to the precursor gas and scanning the selected region with the localized energy occurs simultaneously. Simultaneous exposure and scanning may be accomplished in several ways. For example, the precursor gas may be provided at a low concentration whereby complete adsorption of the precursor gas in the selected region occurs substantially slower than cooling of the selected region of the substrate in between scans of the localized energy. A majority of the product formed on the selected region of the substrate would thereby occur molecular monolayer-by-monolayer. Growth would occur primarily in the selected regions. Additionally, conversion of gas-phase precursor gas to the product would be limited, thereby limiting precipitation of gas-phase formed product. A sufficiently “low concentration” could be determined experimentally or approximated using equations, when available for the selected precursor gas. Additionally, the precursor gas, localized energy intensity and wavelength, and cooling time can also be optimized with the precursor gas concentration to achieve primarily ALD-type molecular monolayer-by-monolayer reactions instead of CVD-type reactions.

Another example of utilizing simultaneous exposure and scanning includes exposing the selected region to a reagent gas reactive with the precursor gas at an elevated temperature but is substantially non-reactive with the precursor gas at temperatures less than the elevated temperature. In this example, scanning the selected region with the localized energy heats the selected region of the substrate to at least the elevated temperature, whereby the reagent gas reacts with adsorbed precursor in the selected region to form the product. However, the selected region would cool (either actively or passively) when not being scanned by the localized energy. Reaction between the reagent gas and the precursor gas would diminish as the selected region cooled. Precursor gas could adsorb unreacted to the selected region in between scans with the localized energy. The timing of the scans and other process conditions can be controlled such that a majority of the product formed on the selected region of the substrate would occur molecular monolayer-by-monolayer and growth would occur primarily in the selected regions. Additionally, conversion of gas-phase precursor gas to the product can be limited, thereby limiting precipitation of gas-phase formed product. Non-limiting exemplary combinations that could be used include an aminosilane precursor gas and an oxygen source, such as ozone, as the reagent gas. That combination would produce SiO₂ films on the heated selected regions. Likewise, an aminosilane precursor gas plus a nitrogen source, such as ammonia, as the reagent gas would produce nitride films on the heated selected regions.

Less of the precursor gas may be used to create the thin film, than a comparable thin film made using the same reactants but in a spatial atomic layer deposition process or a pulse atomic layer deposition process. For a pulse ALD process, each reactant (e.g., precursor gas and reagent gas) may be separately pumped into a reaction chamber and then evacuated from the chamber before the next reactant is introduced. The embodiments disclosed herein advantageously potentially reduce both the time required for introducing the reactants and waste of the reactants, since the precursor gas (and any reagent gases) can be continuously present, but reaction is controlled by heating only selected regions of the substrate. Furthermore, the thin film may be grown faster using the methods and systems disclosed herein than a comparable thin film made using a pulse atomic layer deposition process operating with a similar backside substrate temperature.

In certain embodiments, the entire substrate may be selected for coating. Or stated another way, the entire substrate can be the selected region. Alternatively, multiple, discontiguous selected regions on one or more substrates may be coated using the methods and systems disclosed herein.

A variety of precursor gases may be used. For example, by way of non-limiting example, the precursor gas may comprise an amino-based silicon precursor, such as an amino-based silicon precursor that includes at least one nitrogen atom directly bonded to a silicon atom. Non-limiting examples of amino-based silicon precursors include bis-diethylaminosilane (BDEAS), ORTHRUS, tris-diethylaminosilane (TDMAS or 3DMAS), bis-tert-butylaminosilane (BTBAS), Diisopropylaminosilane (DIPAS), bis-diisopropylaminodisilane (BDIPADS), Trisilylamine (TSA), neopentasilane, N (SiH)₃)₃ Tris (isopropylamino) silane (TIPAS), bis (ethylmethyl aminosilane) (BEMAS) and diisopropylamino trichlorosilane (DIPATCS).

In the methods disclosed herein, exposing the substrate to the precursor gas may include providing a reaction chamber; and pressurizing the reaction chamber, at least partially, with a single dose of the precursor gas or continuously pumping the precursor gas into the reaction chamber. The entire exposed surface of the substrate may be exposed to the precursor gas (or other reagent gases). Product growth will occur primarily only in the selected regions scanned with the localized energy. Certain selected regions may be scanned more than others to build up product growth more on those certain selected regions. The methods may include first evacuating the reaction chamber to 0.000001 Torr to 100 Torr prior to pressurizing the reaction chamber. The reaction chamber may be pressurized to pressures ranging from 10 Torr to atmospheric pressure with the precursor gas, a secondary gas, additional gases, or mixtures thereof.

The geometry of the substrate is not limited. The substrate may be a curved surface, a flat surface, or a roll-to-roll film.

Repeatedly exposing the selected region to a precursor gas and scanning the selected region with the localized energy may include moving the substrate, moving the localized energy source, or both. For example, alternately positioning the localized energy source over selected regions of the substrate may involve moving the localized energy source in a x-y plane above the substrate, such as in a path parallel to the substrate.

In certain embodiments, it will be beneficial to move the substrate relative to the localized energy source, rather than moving the localized energy source.

Scanning the selected region with the localized energy may involve emitting pulsed localized energy or emitting continuous localized energy. The width of the localized energy may be increased or decreased while scanning the selected region with the localized energy, to introduce different patterns and/or different growth rates on portions of the selected region.

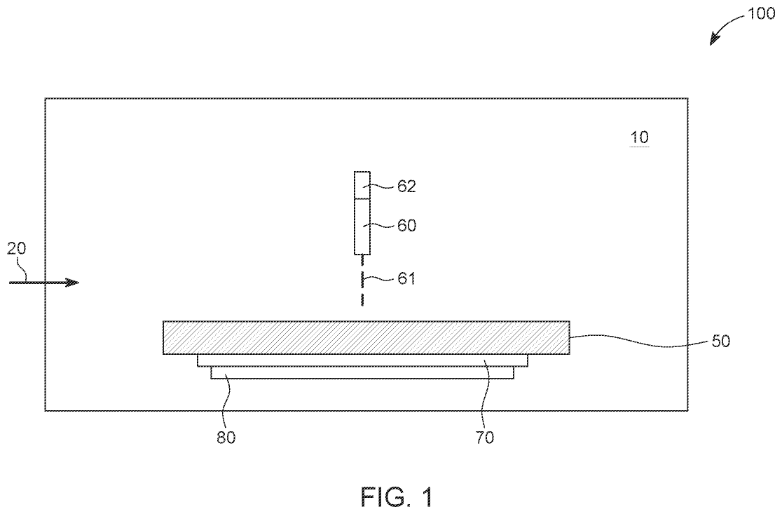

Turning now to systems for depositing thin films on substrates, FIG. 1 illustrates a cross-sectional view of one embodiment of an exemplary system 100. The system includes a reaction chamber 10, including an inlet 20 for introducing a precursor gas into the reaction chamber 10. A laser source 60 is configured to direct a laser beam 61 towards a selected region of a substrate 50. In the system 100, exposing the selected region to the precursor gas 20 and scanning the selected region with the laser beam 61 occurs simultaneously. The precursor gas 20 is provided at a low concentration. Complete adsorption of the precursor gas 20 in the selected region occurs substantially slower than cooling of the selected region of the substrate 50 in between scans of the laser beam 61.

The laser source 60 may be used to scan (or “write”) a variety of patterns or may be used to scan the entire substrate 50. The scan time can be governed by adsorption kinetics of the low concentration precursor gas 20. If it takes 3 seconds for theoretical complete saturation of the low concentration precursor gas 20, then the scans with the laser beam 61 may be repeated every 3 seconds. Multiple laser sources 60 may be used to increase the frequency of scanning the substrate 50.

The reaction chamber 10 may be a cold-wall reaction chamber. Reaction between the precursor gas 20 and interior surfaces of the reaction chamber 10 may be minimal.

The system 100 includes a positioning system 70 configured to alternately position the laser source 60 over selected regions of the substrate 50 (either by moving the laser source 60 or the substrate 50, or combinations of moving both), when the substrate 50 is present in the reaction chamber 10.

In FIG. 1, the positioning system 70 is shown operably connected to the substrate 50. Alternatively, the positioning system 70 may be operably connected to the laser source 60.

FIG. 1 further illustrates a carriage 80. The carriage 80 is configured to advance the substrate 50 through the reaction chamber 10. In FIG. 1, the positioning system 70 and the carriage 80 work together to position the substrate 50 relative to the laser source 60. The positioning system 70 is configured to move the substrate 50 in an x-y plane below the laser source 60 and transverse to the movements of the carriage 80. The carriage 80 moves the substrate 50 forward and reverse in the z direction.

For cylindrical systems, the carriage 80 may be configured to rotate axially a cylindrical substrate holder. For radial systems, the carriage 80 may be configured to rotate radially a circular substrate holder. For linear systems, the carriage 80 may be configured to move linearly a rectangular substrate. Likewise, for roll-to-roll systems, the carriage 80 may be configured to advance/rewind a thin film substrate.

In certain embodiments, the carriage 80 may not be present and all movements of the substrate are performed by the positioning system 70.

In FIG. 1, the laser source 60 is located within the reaction chamber 10; however, the laser source 60 could also be located elsewhere, including outside the reaction chamber 10, and the laser beam 61 transmitted through a window towards the substrate 50.

The system 100 further includes a control system 62 operably connected to the laser source 60. The control system 62 is configured to control the laser source 60. The laser source 60 can emit the laser beam 61 in pulses or continuously.

The precursor gas can be supplied in a single pulse or bolus by a first pump (not shown). Alternatively, the precursor gas can be continuously pumped by the first pump into the reaction chamber 10.

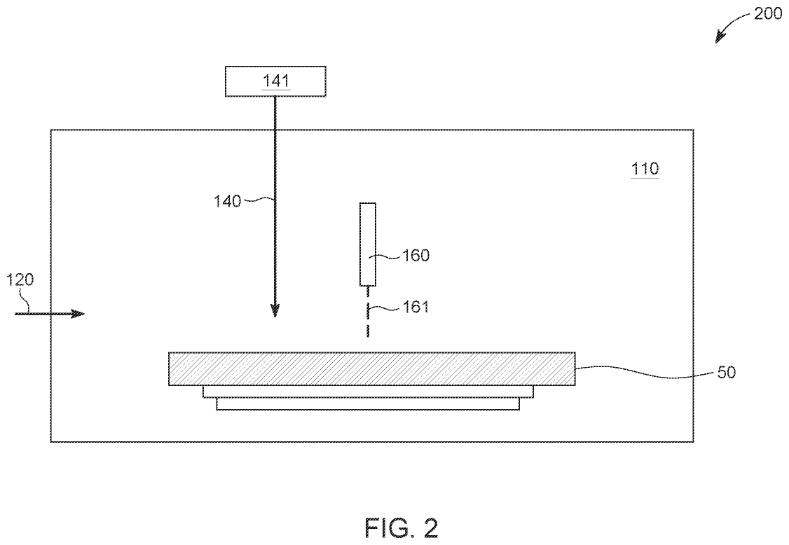

FIG. 2 illustrates a cross-sectional view of one embodiment of an exemplary system 200. System 200 is the same as the system 100 with the addition of a reactant gas supplied via reactant gas supply 140 and reactant gas pump 141. The system includes a reaction chamber 110, including an inlet 120 for introducing a precursor gas into the reaction chamber 110. A laser source 160 is configured to direct a laser beam 161 towards a selected region of a substrate 50.

The system 200 includes a pump 141 for pumping a continuous flow of the reactant gas into the reaction chamber 110. In some embodiments, the pump 141 may not be present.

In the system 200, the precursor gas and the reactant gas are selected to be substantially non-reactive with each other unless activated by the laser beam 161. However, the precursor gas and the reactant gas when activated by the laser beam would form the desired product. Activation of the gases could occur either by absorption of the laser beam directly by the gas molecules and/or thermal activation by heated radiating from the substrate 50 (and any product formed thereon) after scanning of the substrate 50 by the laser beam 161.

In the system 200, if the precursor gas is not directly reactive with the laser beam 161, then the concentration of the precursor gas can be higher. In those embodiments, activation of the higher concentration precursor gas will primarily only occur proximal the regions of the substrate 50 scanned with the laser beam 161.

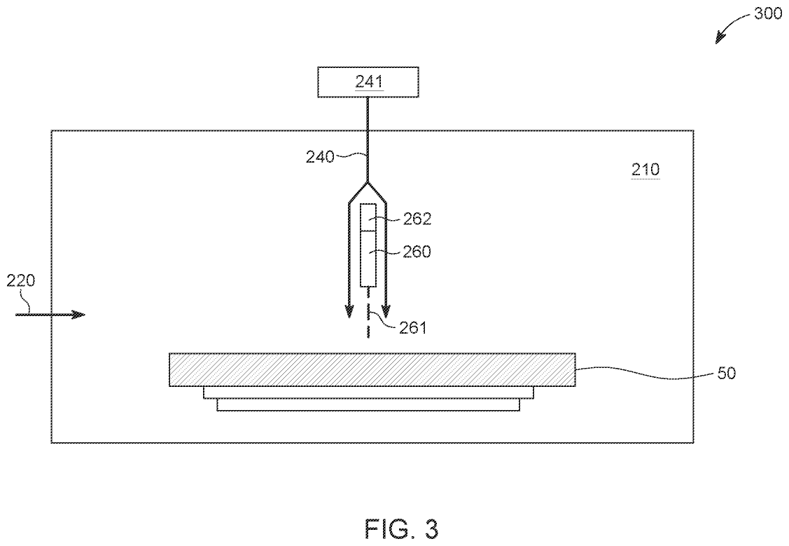

FIG. 3 illustrates a cross-sectional view of one embodiment of an exemplary system 300. System 300 is similar to the system 100 with the addition of a secondary gas supplied via secondary gas orifice 240 and reactant gas pump 241. The system includes a reaction chamber 210, including an inlet 220 for introducing a precursor gas into the reaction chamber 210. A laser source 260 is configured to direct a laser beam 261 towards a selected region of a substrate 50.

The operation of the system 300 is distinct from the systems 100 and 200. In the system 300, the precursor gas may be directly activated by the laser beam 261. The precursor gas is displaced proximally to the selected region to be scanned with the laser beam 261. The secondary gas orifice 240 is configured to produce a gas shroud (or gas curtain) of the secondary gas that displaces at least a portion of the precursor gas proximal a selected region of the substrate to be scanned. A second pump 241 is configured to pump either a continuous or pulsed flow of the secondary gas through the secondary gas orifice 240 at sufficient flow and pressure conditions to generate the gas shroud, during operation of the system 300.

Directing the precursor gas away from the selected region and scanning the selected region with the laser beam 261 may occur simultaneously or substantially simultaneously. For example, directing the precursor gas away from the selected region may be initiated prior to scanning the selected region with the laser and continue while scanning the selected region with the laser beam.

By alternately exposing the selected region of the substrate to the laser beam and the precursor gas multiple times, then a thin film of product grows. Each exposure to the precursor gas some of the precursor gas adsorbing on the selected region of the substrate as an adsorbed precursor. Each subsequent exposure of the selected region of the substrate to the laser beam results in some of the adsorbed precursor converting to a product in the selected region, whereby a thin film of the product is formed on the selected region of the substrate 50. Total pressure in the reaction chamber 210 may be from 10 Torr to atmospheric pressure.

A control system 262 is operably connected to the laser source 260. The control system 262 may also be operably connected to the secondary gas orifice 240. The control system 262 may be configured to pulse the laser beam 261 and production of the gas shroud of the secondary gas. With pulsing, the selected region of the substrate would be exposed to the precursor gas in between pulses of the laser beam 261 and the pulses of the gas shroud.

In each of the systems 100, 200, and 300, the laser beam 61, 161, and 261, respectively, may scan (or “write”) a pattern on the substrate 50 that is a continuous pattern or discontinuous pattern. Or stated another way, the laser beam 61, 161, and 261, respectively, may scan two or more discontiguous selected regions of the substrate 50. The scan time for the pattern may be selected to allow saturated adsorption of the precursor gas on the pattern before scanning the pattern again (e.g., 1-10 seconds). The substrate 50 may be cooled so that portions of the substrate 50 scanned by the laser beam 61, 161, and 261 rapidly cease to activate precursor gas molecules. For example, if a portion of the substrate 50 is scanned every 3 seconds, saturated adsorption of the precursor gas also takes 3 seconds, and the substrate cools below activation temperature within 0.1 seconds, then reactions on the surface of the substrate 50 will primarily be molecular monolayer-by-layer. Additionally, if the substrate 50 is only locally heated by the laser beam 61, 161, and 261, then product will only grow in the region scanned by the laser beam 61, 161, and 261.

The laser source 60, 160, and 260 may be configured to generate a laser beam of any desired width (or a variable width) at the point of hitting the substrate 50, including, for example, widths up to 100 micron or narrower beams such as 1 nm to 50 nm, 1 nm to 30 nm, or 1 nm to 20 nm. Any of the systems disclosed herein can include one or more mirrors to vary the angle or width of the laser beam. Likewise, a power controller can be used to vary the power of the laser beam at different points while scanning the substrate 50.

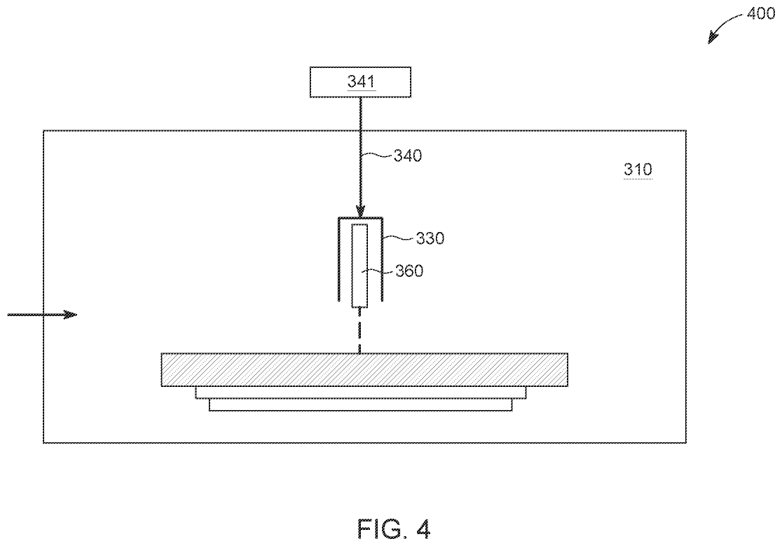

FIG. 4 illustrates a cross-sectional view of one embodiment of an exemplary system 400. System 400 is the same as the system 300, with the addition of the physical shroud 330 operably connected to the secondary gas orifice 340. The physical shroud 330 is configured to facilitate forming the gas shroud with the secondary gas. The system 400 (and the systems 100, 200, and 300) may include multiple laser sources 360 and secondary gas orifices 340 within the reaction chamber 310 for growing the product on multiple selected regions of the substrate 50 simultaneously.

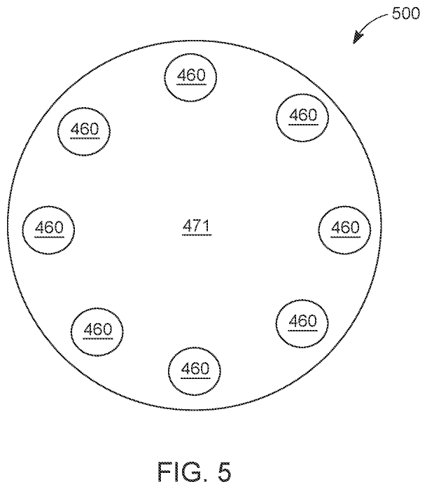

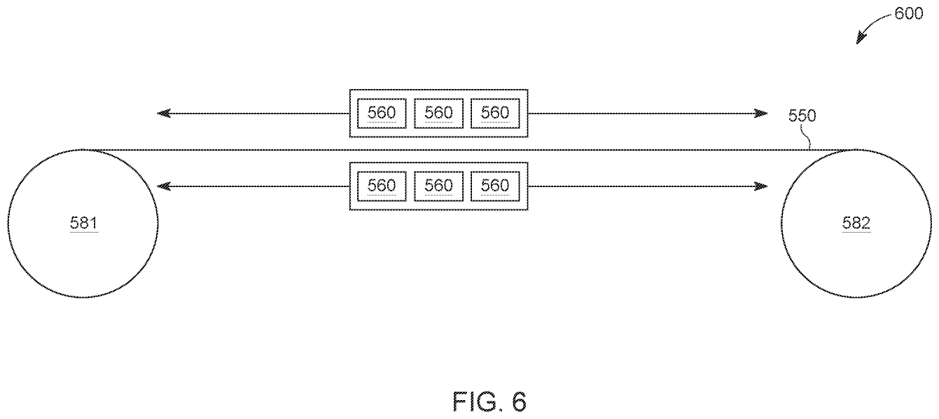

Several different reaction chamber configurations are possible utilizing the methods and systems disclosed herein. Two exemplary configurations are illustrated in FIGS. 5 and 6.

FIG. 5 illustrates an exemplary rotary system 500. The system 500 includes a disc-shaped platen or carrier 471 that rotates about a central axis and is the positioning system. Substrates (not shown), such as disc-shaped silicon wafers, can be mounted on the surface of the platen 471. Substrates of other types and shapes may also be utilized. The platen 471 spins about its axis within a reaction chamber (not shown). The substrates are transported along a circular transport path sequentially passing beneath each of the laser sources 460. Each laser source 460 may write the same or different patterns. When writing the same pattern, the system 500 would benefit from utilizing a single precursor gas supply in the reaction chamber while each laser source 460 writes the same pattern. The platen 471 would not necessarily need to spin when the same pattern was being written by each of the laser sources 460.

When some of the laser sources 460 write different patterns, then after a first pattern product thin film had been grown, then the substrate could be rotated by the platen 471 to the next laser source 460 for growing a different thin film pattern using the same precursor gas. Likewise, some of the laser sources 460 could be replaced with different equipment, such as printheads. A first laser source 460 could be used to grow a thin film product pattern on a substrate and then the substrate rotated to a printhead for further processing. After the further processing, the substrate could be rotated to a second laser source 460 for growing a different thin film product pattern on the same substrate.

FIG. 6 illustrates an exemplary roll-to-roll system 600. The substrate 550 is a thin film rolled from the unwind roll 581 to the wind-up roll 582. In this embodiment, the unwind roll 581 and the wind-up roll 582 can function as either a carriage system or as part of the positioning system. In the illustrated embodiment, the light sources 560 also shuttle back-and-forth over the substrate 550 while the substrate 550 moves. Reaction product only forms proximal the underside of the laser sources 560. Therefore, the unwind roll 581 and the wind-up roll 582 can be within the reaction chamber, without undesired product building up on undesired surfaces. In the system 600, the laser sources 560 are located on both sides of the thin film substrate 550. Optionally, the laser sources 560 may only be located on one side of the thin film substrate 550.

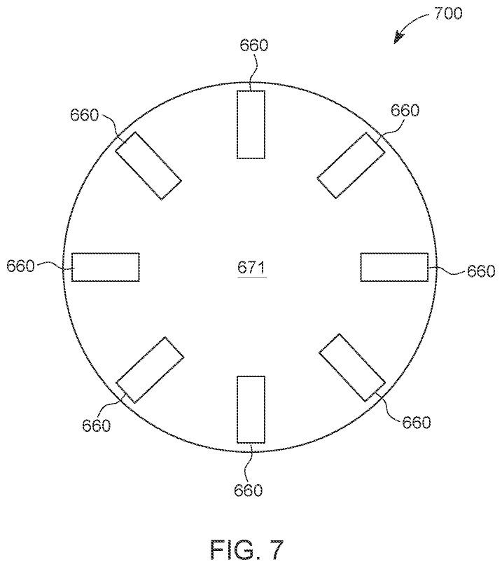

FIG. 7 illustrates an exemplary rotary system 700. The system 700 includes a disc-shaped platen or carrier 671 that rotates about a central axis and is the positioning system. Substrates (not shown), such as disc-shaped silicon wafers, can be mounted on the surface of the platen 671. Substrates of other types and shapes may also be utilized. The platen 671 spins about its axis within a reaction chamber (not shown). The substrates are transported along a circular transport path sequentially passing beneath each of the heat lamps 660 (such as an 8-inch halogen heat lamp). Each heat lamp 660 scans the entire substrate as it passes underneath the heat lamp 660.

Unlike the system 500, for the system 700, it is beneficial to rotate the platen 671 during processing of the substrates even though each of the heat lamps 660 performs the same function. A single precursor gas can be supplied in the reaction chamber. Precursor gas molecules adsorb to the substrate in between temporary heat exposures. Each time a substrate passes underneath a heat lamp 660, an ALD reaction is completed. Accordingly, with 8 heat lamps 660, each revolution of the platen 671 results in each of the substrates experiencing 8 ALD reactions.

The methods described herein of directing the precursor gas away from the selected region may be used during scanning the substrates with the heat lamps in the system 700. Likewise, the methods described herein of simultaneously exposing the selected region to the precursor gas and scanning the selected region with the localized energy may be used with the system 700.

One of skill in the art will understand that many features of the various exemplary systems disclosed herein can be combined or interchanged. For example, any of the systems disclosed herein may include multiple laser sources configured for scanning the same or different patterns. Likewise, any of the systems disclosed herein may be modified for scanning both sides of a substrate. Additionally, rapid thermal processing (RTP) lamps may be used instead of laser sources. The pattern “written” or scanned by the RTP lamps may be broader than the pattern scanned by most laser beams. Additionally, the resolution of the thin film grown on the selected region of the substrate may be lower than compared to the resolution resulting from using a laser source.

The systems disclosed herein may be integrated with other processes without damaging the other processing system. The ALD reaction product primarily only grows on surfaces scanned by the localized energy source. Therefore, printheads and other processing equipment can be in the same reaction chamber as the ALD equipment. For example, a printhead within the reaction chamber could provide additional processing of the substrate before, after, or during generation of the thin film product at the selected region. This could potentially reduce both equipment costs and reduce floor space needed for manufacturing semiconductors and other devices.

The phrase “operably connected to” or “operably coupled to” refers to any form of interaction between two or more entities, including mechanical, electrical, magnetic, electromagnetic, fluid, and thermal interaction. Two entities may interact with each other even though they are not in direct contact with each other. For example, two entities may interact with each other through an intermediate entity.

Without further elaboration, it is believed that one skilled in the art can use the preceding description to utilize the present disclosure to its fullest extent. The examples and embodiments disclosed herein are to be construed as merely illustrative and exemplary and not a limitation of the scope of the present disclosure in any way. It will be apparent to those having skill in the art, and having the benefit of this disclosure, that changes may be made to the details of the above-described embodiments without departing from the underlying principles of the disclosure herein.

1. A method of forming a thin film, the method comprising:
providing a substrate with a selected region to be coated; and
repeatedly:
exposing the selected region to a precursor gas, resulting in some of the precursor gas adsorbing on the selected region of the substrate as an adsorbed precursor; and
scanning the selected region with a localized energy, resulting in at least some of the adsorbed precursor in the selected region converting to a product with a growth-rate less than or equal to about one molecular layer of the product;
each subsequent exposure of the selected region of the substrate to the precursor gas and the localized energy resulting in at least some of the adsorbed precursor converting to the product in the selected region, whereby a thin film of the product is formed in the selected region of the substrate.

2. The method of claim 1, wherein scanning the selected region with the localized energy heats the selected region and enables conversion of at least some of the adsorbed precursor to the product, wherein scanning the selected region with the localized energy causes photolytic decomposition of at least some of the adsorbed precursor and enables conversion of the adsorbed precursor to the product, or a combination of both.

3. The method of claim 1, further comprising cooling the selected region after scanning the selected region with the localized energy.

4. The method of claim 3, wherein cooling the selected region comprises allowing enough time in between scans with the localized energy to allow the selected region of the substrate to cool to temperatures at which the precursor gas is substantially non-reactive and/or to temperatures at which the precursor gas does not substantially adsorb to the selected region of the substrate.

5. The method of claim 1, further comprising directing the precursor gas away from the selected region prior to scanning the selected region with the localized energy, thereby limiting conversion of gas-phase precursor gas to the product, and thereby limiting precipitation of gas-phase formed product.

6. The method of claim 1, further comprising simultaneously directing the precursor gas away from the selected region and scanning the selected region with the localized energy.

7. The method of claim 1, wherein exposing the selected region to the precursor gas and scanning the selected region with the localized energy occurs simultaneously.

8. The method of claim 7, wherein the precursor gas is provided at a low concentration whereby complete adsorption of the precursor gas in the selected region occurs substantially slower than cooling of the selected region of the substrate in between scans of the localized energy, whereby a majority of the product formed on the selected region of the substrate occurs molecular monolayer-by-monolayer, and thereby also limiting conversion of gas-phase precursor gas to the product and thereby limiting precipitation of gas-phase formed product.

9. The method of claim 7, further comprising exposing the selected region to a reagent gas reactive with the precursor gas at an elevated temperature but is substantially non-reactive with the precursor gas at temperatures less than the elevated temperature, and wherein scanning the selected region with the localized energy heats the selected region of the substrate to at least the elevated temperature, whereby the reagent gas reacts with adsorbed precursor in the selected region to form the product, and thereby limiting conversion of gas-phase precursor gas to the product and thereby limiting precipitation of gas-phase formed product.

10. The method of claim 9, further comprising cooling the selected region to a temperature less than the elevated temperature after scanning the selected region with the localized energy, whereby reaction between the reagent gas and the precursor gas is limited during adsorption of the precursor gas to newly formed product in the selected region of the substrate, whereby a majority of the product formed on the selected region of the substrate occurs molecular monolayer-by-monolayer.

11. The method of claim 1, wherein less of the precursor gas is used to create the thin film than a comparable thin film made using a spatial atomic layer deposition process or a pulse atomic layer deposition process.

12. The method of claim 1, wherein exposing the substrate to the precursor gas comprising:
providing a reaction chamber; and
pressurizing the reaction chamber with a single dose of the precursor gas OR continuously pumping the precursor gas into the reaction chamber.

13. The method of claim 1, wherein the thin film is grown faster than a comparable thin film made using a pulse atomic layer deposition process operating with a similar backside substrate temperature.

14. The method of claim 1, wherein the substrate is a curved surface, a flat surface, or a roll-to-roll film.

15. The method of claim 1, wherein repeatedly exposing the selected region to a precursor gas and
and scanning the selected region with the localized energy comprises moving the substrate, moving a localized energy source, or both.

16. The method of claim 1, further comprising selecting a wavelength of the localized energy that is preferentially absorbed more by the substrate than by the precursor gas.

17. The method of claim 1, wherein scanning the selected region with the localized energy comprises emitting pulsed localized energy or emitting continuous localized energy and utilizes one or more localized energy.

18. The method of claim 1, wherein the localized energy comprises a laser beam, radiation from an infrared, visible, or ultraviolet light source, or combinations thereof, and wherein when the localized energy comprises a laser beam the product is formed with high resolution in the selected region of the substrate.

19. A system for depositing a thin film on a substrate, the system comprising:
a reaction chamber, including an inlet for introducing a precursor gas into the reaction chamber;
a secondary gas orifice operably coupled to a secondary gas supply system, the secondary gas orifice configured to produce a gas shroud of the secondary gas that displaces at least a portion of the precursor gas proximal a selected region of the substrate, when the substrate is present in the reaction chamber; and
a localized energy source configured to direct a localized energy towards the selected region of a substrate in coordination with production of the gas shroud, when the substrate is present in the reaction chamber,
to thereby alternately expose the selected region of the substrate to the localized energy and the precursor gas multiple times, resulting in some of the precursor gas adsorbing on the selected region of the substrate as an adsorbed precursor, and each subsequent exposure of the selected region of the substrate to the localized energy resulting in some of the adsorbed precursor converting to a product in the selected region, whereby a thin film of the product is formed on the selected region of the substrate.

20. The system of claim 1, wherein the localized energy source comprises a rapid thermal processing lamp, a laser source, or combinations thereof.
